(19) United States
(12) Patent Application Publication
(10) Pub. No.: US 2019/0364672 A1
(43) Pub. Date: Nov. 28, 2019

(54) BI-DIRECTIONAL OPTICAL SUB ASSEMBLY CONNECTING STRUCTURE

(71) Applicant: XAVi Technologies Corporation, New Taipei City (TW)

(72) Inventor: KUO-HO LIAO, New Taipei City (TW)

(21) Appl. No.: 16/233,459

(22) Filed: Dec. 27, 2018

(30) Foreign Application Priority Data
May 23, 2018 (TW) 107117570

(51) Int. Cl. H05K 3/36; H05K 3/34; H05K 1/14; H05K 1/18

(52) U.S. Cl. CPC H05K 3/363; H05K 3/3494; H05K 2201/10621; H05K 1/189; H05K 1/147

(57) ABSTRACT

A bi-directional optical sub assembly connecting structure which is disclosed includes a first connecting plate, a second connecting plate, a connector, a first circuit, and a second circuit. The first connecting plate includes a plurality of first contacts for electrically connecting to a first transmitting end. The second connecting plate connects with the first connecting plate and includes a plurality of second contacts for electrically connecting to a second transmitting end. The connector connects with the first connecting plate for electrically connecting to a printed circuit board. The first circuit is located on the first connecting plate and electrically connected to the plurality of first contacts and the connector. The second circuit is located on the first connecting plate and the second connecting plate and electrically connected to the plurality of second contacts and the connector.

### BACKGROUND OF THE INVENTION

### 1. Field of the Invention

The present invention relates to a bi-directional optical sub assembly connecting structure; more particularly, the present invention relates to a bi-directional optical sub assembly connecting structure which is used for electrically connect a bi-directional optical sub assembly to a printed circuit board.

### 2. Description of the Related Art

To meet the market requirements of high-speed wire transmission, many manufacturers have developed communication equipment based on fiber optic transmission technology in recent years. As shown in FIG. 1, this kind of communication equipment has a bi-directional optical sub assembly 600, a printed circuit board 500, and a set of L-shaped pins 700. The bi-directional optical sub assembly 600 connects with a fiber optic cable to transmit electronic signals. Moreover, the bi-directional optical sub assembly 600 comprises a first transmitting end 610 and a second transmitting end 620. The first transmitting end 610 is soldered to an end of the set of L-shaped pins 700, and the other end of the set of L-shaped pins 700 is soldered to the printed circuit board 500. The second transmitting end 620 directly connects with the printed circuit board 500 by soldering, too. The bi-directional optical sub assembly 600 can transmit electronic signals to the printed circuit board 500 through the connection of the pins 700. However, the process of soldering both ends of the pins 700 to the first transmitting end 610 and the printed circuit board 500 has to be carried out manually. Also, executing the soldering is very difficult. For example, during the forming process of the pins 700, the pins 700 have to be bent by a special bending jig. However, there is still a risk of damage to the internal components of the bi-directional optical sub assembly 600 even when the special bending jig is used in the forming process. Moreover, the structure of the pins 700 and the bi-directional optical sub assembly 600 is likely to form solder bridges, which cause solder shorts during the soldering process. Furthermore, according to practical experiments, the pins 700 cause interference with the transmission of signals, so they are not suitable for the high-speed communication specification of at least 10 Gbit/s. In addition, when the bi-directional optical sub assembly 600 transmits electronic signals, it causes electromagnetic interference.

In order to solve the problems caused by the above-mentioned pins 700, two kinds of connecting plates 800 and 800a (as shown in FIG. 2) are provided to replace the pins 700. The connecting plate 800 connects the first transmitting end 610 to the printed circuit board 500 by soldering. The connecting plate 800a connects the second transmitting end 620 to the printed circuit board 500 by soldering. According to practical experiments, the connecting plates 800 and 800a with a plate-like structure are suitable for the high-speed communication specification of at least 10 Gbit/s to meet the requirement of high-speed transmission. However, the degree of difficulty in soldering the connecting plates 800 and 800a to the printed circuit board 500 is still high. Moreover, the position of the bi-directional optical sub assembly 600 has to be additionally fixed during the soldering process. Furthermore, a shielding housing still has to be added to solve the problem of electromagnetic interference from the bi-directional optical sub assembly 600. In addition, when the bi-directional optical sub assembly 600 as shown in FIG. 2 transmits electronic signals, it causes electromagnetic interference.

Therefore, it is desirable to provide an improved connecting structure which can electrically connect a bi-directional optical sub assembly to a printed circuit board easily to mitigate and/or obviate the aforementioned problems.

### SUMMARY OF THE INVENTION

It is a main object of the present invention to provide a bi-directional optical sub assembly connecting structure which can easily electrically connect a bi-directional optical sub assembly to a printed circuit board.

In order to achieve the above object, the present invention provides a bi-directional optical sub assembly connecting structure for electrically connecting a bi-directional optical sub assembly to a printed circuit board. The bi-directional optical sub assembly comprises a first transmitting end, a second transmitting end, and a main body. The bi-directional optical sub assembly connecting structure comprises a first connecting plate, a second connecting plate, a connector, a first circuit, and a second circuit. The first connecting plate comprises a plurality of first contacts for electrically connecting to the first transmitting end. The second connecting plate connects with the first connecting plate and comprises a plurality of second contacts for electrically connecting to the second transmitting end. The connector connects with the first connecting plate for electrically connecting to the printed circuit board. The first circuit is located on the first connecting plate and electrically connected to the plurality of first contacts and the connector. The second circuit is located on the first connecting plate and the second connecting plate and electrically connected to the plurality of second contacts and the connector.

According to one embodiment of the present invention, the first circuit is located on a face of the first connecting plate which faces away from the main body. The second circuit is located on a face of the first connecting plate which faces the main body and on a face of the second connecting plate which faces the main body.

According to one embodiment of the present invention, the bi-directional optical sub assembly connecting structure of the present invention further comprises an electromagnetic shielding member for covering the main body. The electromagnetic shielding member comprises a top shielding plate and a side shielding plate. The top shielding plate connects the second connecting plate and the side shielding plate.

According to one embodiment of the present invention, the top shielding plate is configured to cover a top surface of the main body. The second connecting plate and the side shielding plate are configured to respectively cover two side surfaces of the main body which are opposite to each other.

According to one embodiment of the present invention, the bi-directional optical sub assembly connecting structure further comprises a plurality of male fixing members. Each of the male fixing members connects with the second connecting plate or the side shielding plate.

According to one embodiment of the present invention, when the plurality of male fixing members are fixed to the printed circuit board, the second connecting plate and the electromagnetic shielding member clamp the main body such that the main body is fastened to the printed circuit board.

According to one embodiment of the present invention, the printed circuit board further comprises a plurality of female fixing members, and the plurality of male fixing members are configured to be fixed to the plurality of female fixing members, respectively.

According to one embodiment of the present invention, the bi-directional optical sub assembly connecting structure further comprises a protective film covering the first connecting plate, the second connecting plate, and the electromagnetic shielding member.

According to one embodiment of the present invention, the protective film comprises a plurality of void areas. One of the void areas is located at the top shielding plate, and another of the void areas is located at the side shielding plate.

According to one embodiment of the present invention, the second circuit is located on a face of the second connecting plate which faces the side shielding plate and on a face of the first connecting plate. The first circuit is located on another face of the first connecting plate.

### BRIEF DESCRIPTION OF THE DRAWINGS

FIG. 1 is a schematic drawing of a prior art bi-directional optical sub assembly connecting with a printed circuit board through pins;

FIG. 2 is a schematic drawing of a prior art bi-directional optical sub assembly connecting with the printed circuit board through connecting plates;

FIG. 3 is a schematic drawing of a bi-directional optical sub assembly connecting with a printed circuit board through a bi-directional optical sub assembly connecting structure according to one embodiment of the present invention;

FIG. 4 is a schematic drawing of the bi-directional optical sub assembly, the bi-directional optical sub assembly connecting structure, and the printed circuit board when they are shown separate according to one embodiment of the present invention;

FIG. 5 is a schematic drawing of the bi-directional optical sub assembly connecting structure according to one embodiment of the present invention;

FIG. 6 is a schematic drawing of the bi-directional optical sub assembly connecting structure shown from another angle according to one embodiment of the present invention; and

FIG. 7 shows a diagram of the system structure of the bi-directional optical sub assembly, the bi-directional optical sub assembly connecting structure, and the printed circuit board according to one embodiment of the present invention.

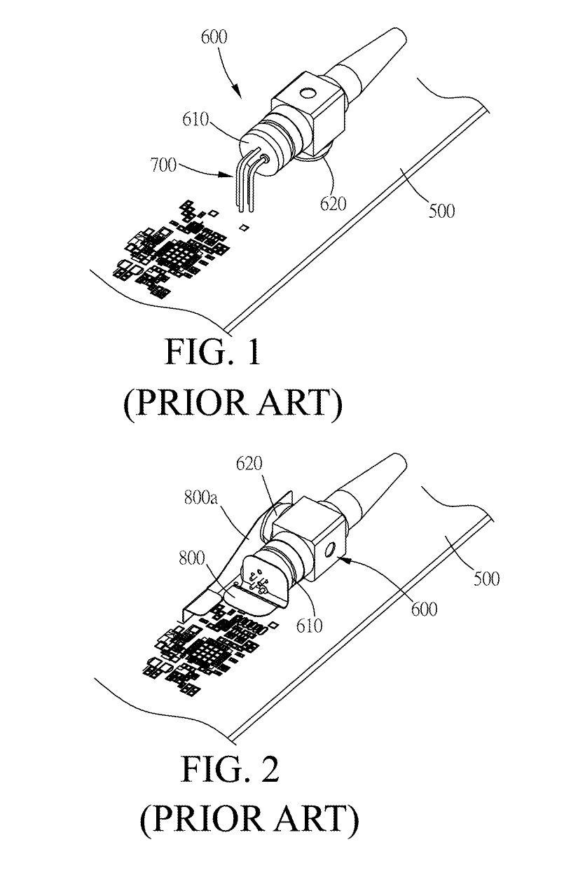

### DETAILED DESCRIPTION OF THE PREFERRED EMBODIMENT

The advantages and innovative features of the invention will become more apparent from the following detailed description when taken in conjunction with the accompanying drawings.

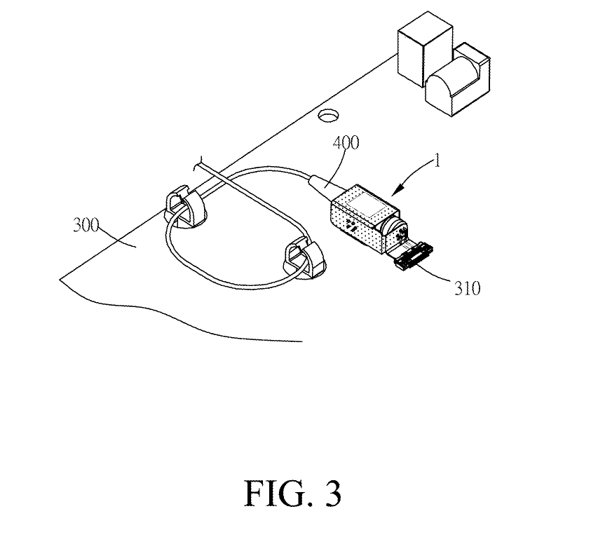

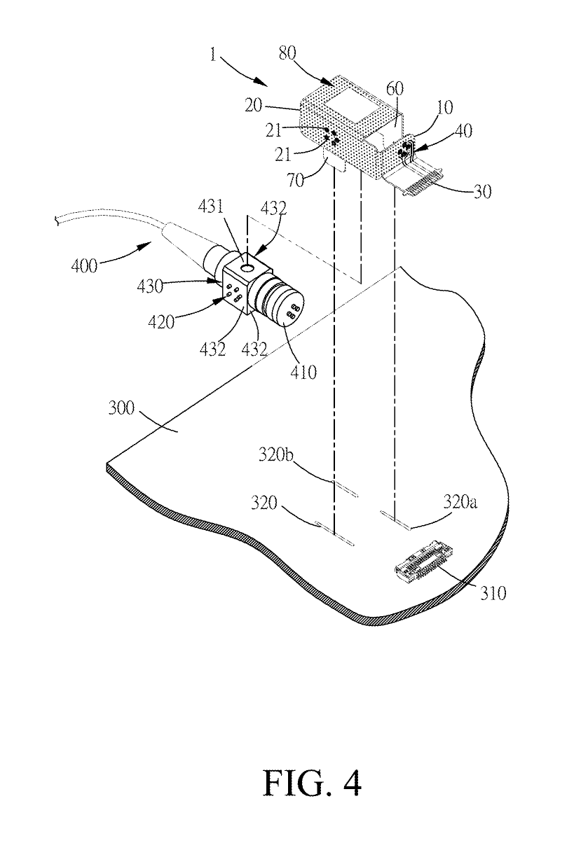

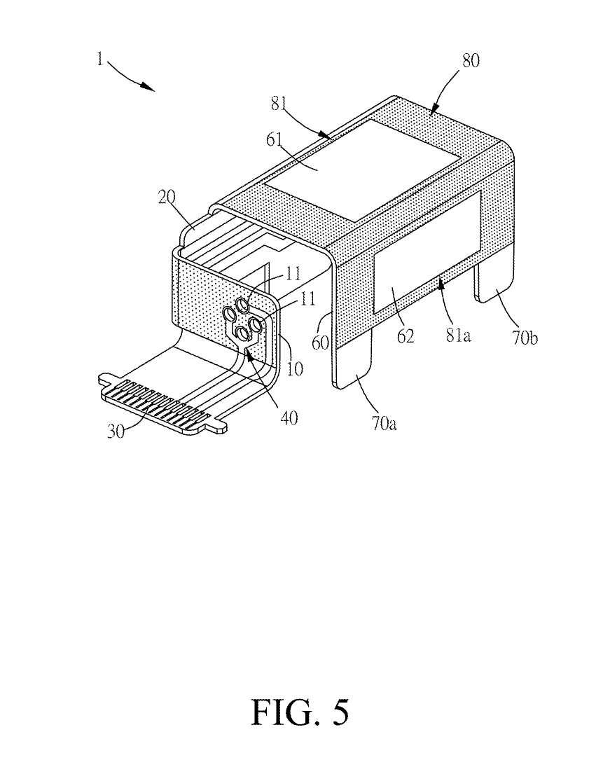

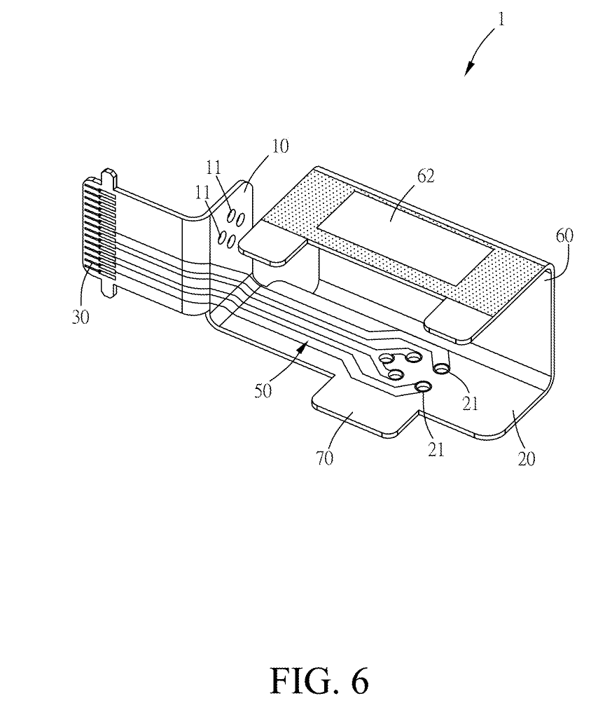

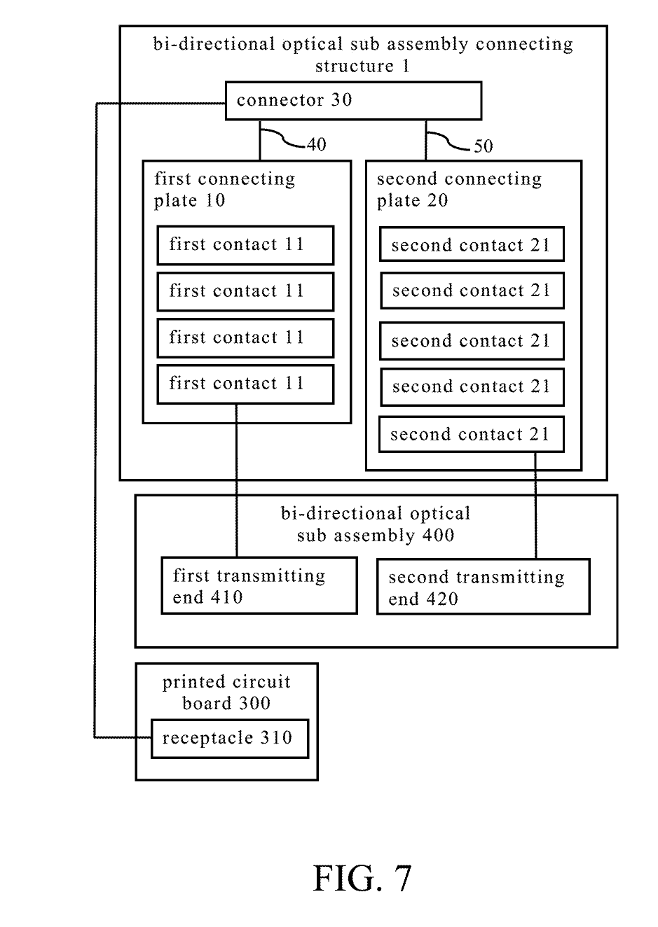

Please refer to FIG. 3 to FIG. 7 for the following paragraphs regarding a bi-directional optical sub assembly connecting structure according to one embodiment of the present invention. FIG. 3 is a schematic drawing of a bi-directional optical sub assembly connecting with a printed circuit board through a bi-directional optical sub assembly connecting structure according to one embodiment of the present invention. FIG. 4 is a schematic drawing of the bi-directional optical sub assembly, the bi-directional optical sub assembly connecting structure, and the printed circuit board when they are shown separate according to one embodiment of the present invention. FIG. 5 is a schematic drawing of the bi-directional optical sub assembly connecting structure according to one embodiment of the present invention. FIG. 6 is a schematic drawing of the bi-directional optical sub assembly connecting structure shown from another angle according to one embodiment of the present invention. FIG. 7 shows a diagram of the system structure of the bi-directional optical sub assembly, the bi-directional optical sub assembly connecting structure, and the printed circuit board according to one embodiment of the present invention.

As shown in FIG. 3 and FIG. 4, in one embodiment of the present invention, a bi-directional optical sub assembly connecting structure 1 is used for mounting a bi-directional optical sub assembly 400 on a printed circuit board 300 and allowing the bi-directional optical sub assembly 400 and the printed circuit board 300 to be electrically connected to each other and transmit signals to each other. The printed circuit board 300 comprises a receptacle 310 and three female fixing members 320, 320a, and 320b. As a specific example, the bi-directional optical sub assembly 400 is a fiber optic transmission element and comprises a first transmitting end 410, a second transmitting end 420, and a main body 430. The first transmitting end 410 is a transmitter (Tx) module, which is also cylinder-like shaped and having four transmitting protruding points. The second transmitting end 420 is a receiver (Rx) module having five transmitting protruding points. The main body 430 comprises a top surface 431 and a plurality of side surfaces 432. The first transmitting end 410 and the second transmitting end 420 are located on two adjacent side surfaces 432 of the main body 430, respectively. The bi-directional optical sub assembly connecting structure 1 comprises a first connecting plate 10, a second connecting plate 20, a connector 30, a first circuit 40, a second circuit 50, an electromagnetic shielding member 60, three male fixing members 70, 70a, and 70b, and a protective film 80.

In one embodiment of the present invention, as shown in FIG. 4 and FIG. 5, the first connecting plate 10 is a flexible printed circuit board. The first connecting plate 10 comprises four first contacts 11. As a specific example, the four first contacts 11 each are a perforated portion and are for joining to the four transmitting protruding points of the first transmitting end 410, respectively, to be electrically connected to the first transmitting end 410, and the present invention is not limited thereto. In an alternative embodiment, the number of the first contacts 11 can be changed in accordance with the number of the transmitting protruding points of the first transmitting end 410.

In one embodiment of the present invention, as shown in FIG. 4 and FIG. 6, the second connecting plate 20 is a flexible printed circuit board. The second connecting plate 20 connects with the first connecting plate 10. The second connecting plate 20 comprises five second contacts 21. As a specific example, the five second contacts 21 each are a perforated portion and are for joining to the five transmitting protruding points of the second transmitting end 420, respectively, to be electrically connected to the second transmitting end 420, and the present invention is not limited thereto. In an alternative embodiment, the number of the second contacts 21 can be changed in accordance with the number of the transmitting protruding points of the second transmitting end 420.

In one embodiment of the present invention, as shown in FIG. 4 to FIG. 7, the connector 30 connects with the first connecting plate 10. The connector 30 is configured for being inserted into the receptacle 310 such that the connector 30 is electrically connected to the printed circuit board 300. The first circuit 40 is located on a face of the first connecting plate 10 which faces away from the main body 430. The first circuit 40 is electrically connected to the four first contacts 11 and the connector 30 such that the four first contacts 11 are electrically connected to the connector 30. The second circuit 50 is located on a face of the first connecting plate 10 which faces the main body and on a face of the second connecting plate 20 which faces the main body. The second circuit 50 is electrically connected to the five second contacts 21 and the connector 30 such that the five second contacts 21 are electrically connected to the connector 30.

When the plurality of first contacts 11 is attached and electrically connected to the first transmitting end 410, the plurality of second contacts 21 is attached and electrically connected to the second transmitting end 420, and when the connector 30 is inserted into the receptacle 310, the first transmitting end 410 and the second transmitting end 420 are electrically connected to the receptacle 310 because the first circuit 40 is electrically connected between the plurality of first contacts 11 and the connector 30, and the second circuit 50 is electrically connected between the plurality of second contacts 21 and the connector 30.

In one embodiment of the present invention, the electromagnetic shielding member 60 is an L-shaped thin flexible plate. Moreover, the electromagnetic shielding member 60 is for shielding electromagnetic radiation generated when the bi-directional optical sub assembly 400 is operated to prevent electromagnetic radiation affecting other electronic components or to prevent external electromagnetic radiation affecting the bi-directional optical sub assembly 400. The electromagnetic shielding member 60 comprises a top shielding plate 61 and a side shielding plate 62. The top shielding plate 61 connects the second connecting plate 20 and the side shielding plate 62. The top shielding plate 61 is configured to cover the top surface 431 of the main body 430. The second connecting plate 20 and the side shielding plate 62 are configured to cover two side surfaces 432 of the main body 430 which are opposite to each other, respectively. Because the electromagnetic shielding member 60 in conjunction with the second connecting plate 20 wraps the bi-directional optical sub assembly 400, the electromagnetic radiation can be adequately shielded.

In one embodiment, the first connecting plate 10, the second connecting plate 20, the connector 30, the electromagnetic shielding member 60, and the male fixing members 70, 70a, and 70b of the present invention are formed by bending a thin plate which is flexible and pliable and are designed as one piece, which facilitates production and assembly.

In one embodiment, the first circuit 40 of the present invention is located on the outer face of the bi-directional optical sub assembly connecting structure 1. The second circuit 50 is located on the inner face of the bi-directional optical sub assembly connecting structure 1. For example, the first circuit 40 is located on a face of the first connecting plate 10 which faces away from the main body 430. The second circuit 50 is located on a face of the first connecting plate 10 which faces the main body 430 and on a face of the second connecting plate 20 which faces the main body 430. In other words, the second circuit 50 is located on a face of the second connecting plate 20 which faces the side shielding plate 62 of the electromagnetic shielding member 60 and on one face of the first connecting plate 10. The first circuit 50 is located on another face of the first connecting plate 10. Moreover, the first circuit 40 and the second circuit 50 are respectively located on two opposite faces of the connector 30, which is a thin flexible plate, there is more space for the wire layout on both plates on which the first circuit 40 and the second circuit 50 are located. When the first circuit 40 and the second circuit 50 transmit electronic signals and generate electromagnetic radiation, the first connecting plate 10 and the second connecting plate 20 also block and shield electromagnetic radiation generated by the first circuit 40 and the second circuit 50 located on different surfaces. This produces a shielding effect such that the electromagnetic radiation generated by the first circuit 40 and the electromagnetic radiation generated by the second circuit 50 do not interfere with each other so as to prevent the transmission rate of electronic signals from being reduced.

In one embodiment of the present invention, there are three male fixing members 70, 70a, and 70b. One of them (e.g., the male fixing member 70) connects with the second connecting plate 20. The other two of them (e.g., the male fixing members 70a and 70b) connect with the side shielding plate 62. The three male fixing members 70, 70a, and 70b are configured to be fixed to the three female fixing members 320, 320a, and 320b, respectively. However, the present invention is not limited thereto. The number of the male fixing members 70, 70a, and 70b can be changed in accordance with the number of the female fixing members 320, 320a, and 320b. When the three male fixing members 70, 70a, and 70b are fixed to the three female fixing members 320, 320a, and 320b, respectively, thermal energy generated by the operation of the bi-directional optical sub assembly 400 can also be transferred to the printed circuit board 300 through the connection between the male fixing members 70, 70a, and 70b and the female fixing members 320, 320a, and 320b such that the efficiency of the heat dissipation of the bi-directional optical sub assembly 400 is increased. In addition, when the three male fixing members 70, 70a, and 70b are fixed to the three female fixing members 320, 320a, and 320b, respectively, the second connecting plate 20 and the electromagnetic shielding member 60 also clamp the main body 430 of the bi-directional optical sub assembly 400 such that the main body 430 is fastened to the printed circuit board 300. In other words, by using the male fixing members 70, 70a, and 70b together with the second connecting plate 20 and the electromagnetic shielding member 60, the goal of fixing the position of the bi-directional optical sub assembly 400 is accomplished.

In one embodiment of the present invention, the protective film 80 is a thin film (shown as dotted areas in FIG. 4 to FIG. 6) of insulating material (e.g., plastic). The protective film 80 covers the first connecting plate 10, the second connecting plate 20, and the electromagnetic shielding member 60 to protect the first connecting plate 10, the second connecting plate 20, and the electromagnetic shielding member 60 so as to further increase the durability of the first connecting plate 10, the second connecting plate 20, and the electromagnetic shielding member 60. The protective film 80 comprises a plurality of void areas 81, 81a. One of the void areas (e.g., the void area 81) is located at the top shielding plate 61. Another of the plurality of void areas (e.g., the void area 81a) is located at the side shielding plate 62. The two void areas 81 and 81a facilitate the heat dissipation of the top shielding plate 61 and the side shielding plate 62 so that the heat generated when the bi-directional optical sub assembly 400 is operated can be dissipated away from the bi-directional optical sub assembly 400 and the bi-directional optical sub assembly connecting structure 1. This prevents heat accumulation in the bi-directional optical sub assembly 400 and the bi-directional optical sub assembly connecting structure 1, which would degrade the operation of the bi-directional optical sub assembly 400.

As shown in FIG. 4 to FIG. 6, when the bi-directional optical sub assembly 400 needs to be mounted on the printed circuit board 300, first, the four transmitting protruding points of the first transmitting end 410 are joined to the four first contacts 11 and the five transmitting protruding points of the second transmitting end 420 are joined to the five second contacts 21. As a result, the four first contacts 11 are attached and electrically connected to the first transmitting end 410, and the five second contacts 21 are attached and electrically connected to the second transmitting end 420. Also, the bi-directional optical sub assembly 400 is fixedly attached to the bi-directional optical sub assembly connecting structure 1. Next, if greater structural strength of the connection between the first transmitting end 410 and the first contacts 11 is required, the first transmitting end 410 can be joined to the first contacts 11 by soldering. Similarly, if greater structural strength of the connection between the second transmitting end 420 and the second contacts 21 is required, the second transmitting end 420 can be joined to the second contacts 21 by soldering, too. It is worthy noted that the soldering procedure for joining the transmitting protruding points of the transmitting ends to the first contacts 11 and the second contacts 21, which are for example perforated portions holes, can be carried out easily. The one who performs soldering only needs to position the transmitting protruding points of the transmitting ends to the first contacts 11 and the second contacts 21, and then apply molten solder to the first contacts 11 and the second contacts 21 such that soldering is easily achieved.

Next, as shown in FIG. 3 to FIG. 5 and FIG. 7, the three male fixing members 70, 70a, and 70b are fixed to the three female fixing members 320, 320a, and 320b, respectively, and the connector 30 is inserted into the receptacle 310 such that the bi-directional optical sub assembly 400 and the bi-directional optical sub assembly connecting structure 1 are mounted on the printed circuit board 300. Moreover, the three male fixing members 70, 70a, and 70b respectively fixed to the three female fixing members 320, 320a, and 320b can be soldered to the three female fixing members 320, 320a, and 320b, respectively. For example, the three male fixing members 70, 70a, and 70b can be soldered to the three female fixing members 320, 320a, and 320b of the printed circuit board 300 directly by using an automatic wave soldering process. Therefore, the first transmitting end 410 and the second transmitting end 420 are electrically connected to the receptacle 310 because the first circuit 40 is electrically connected between the four first contacts 11 and the connector 30, and the second circuit 50 is electrically connected between the five second contacts 21 and the connector 30. Thus, the electronic signals of the bi-directional optical sub assembly 400 can be transmitted to the printed circuit board 300. In addition, because the electromagnetic shielding member 60 in conjunction with the second connecting plate 20 wraps the bi-directional optical sub assembly 400, the electromagnetic radiation of the bi-directional optical sub assembly 400 can be adequately shielded. The protective film 80 covering the first connecting plate 10, the second connecting plate 20, and the electromagnetic shielding member 60 can increase structural durability. Moreover, the two void areas 81 and 81a facilitate the heat dissipation of the top shielding plate 61 and the side shielding plate 62 so that the heat can be dissipated away from the bi-directional optical sub assembly 400 and the bi-directional optical sub assembly connecting structure 1. This prevents heat accumulation in the bi-directional optical sub assembly connecting structure 1.

With the structural design of the bi-directional optical sub assembly connecting structure 1 of the present invention, the bi-directional optical sub assembly 400 can be fixedly attached to the bi-directional optical sub assembly connecting structure 1 by simply using a single-stage soldering process and the bi-directional optical sub assembly connecting structure 1 can also be conveniently and fixedly attached to the printed circuit board 300 such that the bi-directional optical sub assembly connecting structure 1, the bi-directional optical sub assembly 400, and the printed circuit board 300 are electrically connected to each other and transmit electronic signals to each other. Thus, the bi-directional optical sub assembly connecting structure 1, the bi-directional optical sub assembly 400, and the printed circuit board 300 can be attached to each other without using an external device or mechanism (e.g., a bending jig) for controlling the location of the connection. The bi-directional optical sub assembly connecting structure 1 of the present invention is used for electrically connecting the bi-directional optical sub assembly 400 to the printed circuit board 300 and is also used for fastening the body of the bi-directional optical sub assembly 400 to the printed circuit board 300. In addition, one can easily fasten different kinds of bi-directional optical sub assemblies (e.g., a receptacle type without a pigtail or a pigtail type) to the printed circuit board 300 with the bi-directional optical sub assembly connecting structure 1 of the present invention.

In addition, because the bi-directional optical sub assembly connecting structure 1 is attached to the printed circuit board 300 via direct insertion, the problem of locating the connecting position during the soldering process is eliminated. Moreover, the bi-directional optical sub assembly connecting structure 1 can be quickly attached to or detached from the printed circuit board 300. This improves both product assembly efficiency and product maintenance efficiency. Furthermore, the electromagnetic shielding member 60 in conjunction with the second connecting plate 20 wraps the bi-directional optical sub assembly 400 such that the electromagnetic radiation of the bi-directional optical sub assembly 400 can be shielded. Additionally, when the three male fixing members 70, 70a, and 70b are fixed to the three female fixing members 320, 320a, and 320b, respectively, the electromagnetic shielding member 60 in conjunction with the second connecting plate 20 can clamp the bi-directional optical sub assembly 400. Thus, the goal of fixing the position of the bi-directional optical sub assembly 400 is accomplished. According to practical experiments, the connector 30 with a plate-like structure of the bi-directional optical sub assembly connecting structure 1 is suitable for the high-speed communication specification of at least 10 Gbit/s to meet the requirement of high-speed transmission.

It is noted that the above-mentioned embodiments are only for illustration. It is intended that the present invention cover modifications and variations of this invention provided they fall within the scope of the following claims and their equivalents. Therefore, it will be apparent to those skilled in the art that various modifications and variations can be made to the structure of the present invention without departing from the scope or spirit of the invention.

What is claimed is:

1. A bi-directional optical sub assembly connecting structure, for electrically connecting a bi-directional optical sub assembly to a printed circuit board, the bi-directional optical sub assembly comprising a first transmitting end, a second transmitting end, and a main body, the bi-directional optical sub assembly connecting structure comprising:
a first connecting plate comprising a plurality of first contacts for electrically connecting to the first transmitting end;
a second connecting plate connecting with the first connecting plate and comprising a plurality of second contacts for electrically connecting to the second transmitting end;
a connector connecting with the first connecting plate for electrically connecting to the printed circuit board;
a first circuit located on the first connecting plate and electrically connected to the plurality of first contacts and the connector; and
a second circuit located on the first connecting plate and the second connecting plate and electrically connected to the plurality of second contacts and the connector.

2. The bi-directional optical sub assembly connecting structure as claimed in claim 1, wherein the first circuit is located on a face of the first connecting plate which faces away from the main body, and the second circuit is located on a face of the first connecting plate which faces the main body and on a face of the second connecting plate which faces the main body.

3. The bi-directional optical sub assembly connecting structure as claimed in claim 1, further comprising an electromagnetic shielding member for covering the main body, wherein the electromagnetic shielding member comprises a top shielding plate and a side shielding plate, and the top shielding plate connects the second connecting plate and the side shielding plate.

4. The bi-directional optical sub assembly connecting structure as claimed in claim 3, wherein the top shielding plate is configured to cover a top surface of the main body, and the second connecting plate and the side shielding plate are configured to respectively cover two side surfaces of the main body which are opposite to each other.

5. The bi-directional optical sub assembly connecting structure as claimed in claim 3, further comprising a plurality of male fixing members each connecting with the second connecting plate or the side shielding plate.

6. The bi-directional optical sub assembly connecting structure as claimed in claim 5, wherein when the plurality of male fixing members are fixed to the printed circuit board, the second connecting plate and the electromagnetic shielding member clamp the main body such that the main body is fastened to the printed circuit board.

7. The bi-directional optical sub assembly connecting structure as claimed in claim 6, wherein the printed circuit board further comprises a plurality of female fixing members, and the plurality of male fixing members are configured to be fixed to the plurality of female fixing members, respectively.

8. The bi-directional optical sub assembly connecting structure as claimed in claim 3, further comprising a protective film covering the first connecting plate, the second connecting plate, and the electromagnetic shielding member.

9. The bi-directional optical sub assembly connecting structure as claimed in claim 8, wherein the protective film comprises a plurality of void areas, wherein one of the void areas is located at the top shielding plate, and another of the void areas is located at the side shielding plate.

10. The bi-directional optical sub assembly connecting structure as claimed in claim 3, wherein the second circuit is located on a face of the second connecting plate which faces the side shielding plate and on a face of the first connecting plate, and the first circuit is located on another face of the first connecting plate.

11. The bi-directional optical sub assembly connecting structure as claimed in claim 2, further comprising an electromagnetic shielding member for covering the main body, wherein the electromagnetic shielding member comprises a top shielding plate and a side shielding plate, and the top shielding plate connects the second connecting plate and the side shielding plate.

12. The bi-directional optical sub assembly connecting structure as claimed in claim 11, wherein the top shielding plate is configured to cover a top surface of the main body, and the second connecting plate and the side shielding plate are configured to respectively cover two side surfaces of the main body which are opposite to each other.

13. The bi-directional optical sub assembly connecting structure as claimed in claim 11, further comprising a plurality of male fixing members each connecting with the second connecting plate or the side shielding plate.

14. The bi-directional optical sub assembly connecting structure as claimed in claim 13, wherein when the plurality of male fixing members are fixed to the printed circuit board, the second connecting plate and the electromagnetic shielding member clamp the main body such that the main body is fastened to the printed circuit board.

15. The bi-directional optical sub assembly connecting structure as claimed in claim 14, wherein the printed circuit board further comprises a plurality of female fixing members, and the plurality of male fixing members are configured to be fixed to the plurality of female fixing members, respectively.

16. The bi-directional optical sub assembly connecting structure as claimed in claim 11, further comprising a protective film covering the first connecting plate, the second connecting plate, and the electromagnetic shielding member.

17. The bi-directional optical sub assembly connecting structure as claimed in claim 16, wherein the protective film comprises a plurality of void areas, wherein one of the void areas is located at the top shielding plate, and another of the void areas is located at the side shielding plate.

18. The bi-directional optical sub assembly connecting structure as claimed in claim 17, further comprising a plurality of male fixing members each connecting with the second connecting plate or the side shielding plate.

19. The bi-directional optical sub assembly connecting structure as claimed in claim 18, wherein when the plurality of male fixing members are fixed to the printed circuit board, the second connecting plate and the electromagnetic shielding member clamp the main body such that the main body is fastened to the printed circuit board.

20. The bi-directional optical sub assembly connecting structure as claimed in claim 19, wherein the printed circuit board further comprises a plurality of female fixing members, and the plurality of male fixing members are configured to be fixed to the plurality of female fixing members, respectively.
